(19) United States
(12) Patent Application Publication
(10) Pub. No.: US 2008/0232636 A1
(43) Pub. Date: Sep. 25, 2008

(54) Sonic piston

(75) Inventors: Jonathan L. Thurber, Elmhurst, IL (US); James K. Thurber, Elmhurst, IL (US); Kenneth Meyer, Crystal Lake, IL (US); Matthew Honnert, Geneva, IL (US)

Correspondence Address: MARSHALL, GERSTEIN & BORUN LLP, 233 S. WACKER DRIVE, SUITE 6300, SEARS TOWER, CHICAGO, IL, 60606, US

(73) Assignee: SONIC DYNAMICS, LLC, Elmhurst, IL (US)

(21) Appl. No.: 11/726,823

(22) Filed: Mar. 23, 2007

(51) Int. Cl. H05K 5/00; G10K 13/00

(52) U.S. Cl. 381/405; 181/161

(57) ABSTRACT

A motor driven acoustic oscillator or speaker that generates a single frequency acoustic sound. The motor driven acoustic oscillator may be used to emit low frequency (LF) sound waves that generates thrust on an object. The oscillator may be further configured to convert heat energy from a surrounding fluid medium into additional useful mechanical work.

### BACKGROUND

Acoustic speakers are generally driven using a vibrating diaphragm that is driven by a voice coil. While voice coils are generally efficient for producing sound waves in general applications (e.g., playing music and voice), voice coil based speakers may be inefficient in transforming electrical energy into sound energy as a single frequency acoustic signal. In particular, the amount of energy that is wasted in voice coil operation may not provide an efficient electrical to mechanical energy transformation when only single frequency signals are desired. One application which may require single frequency acoustic production at an efficient energy transfer ratio is the use of low frequency acoustic oscillators to produce mechanical thrust. In particular, acoustic or sound energy may be used to impose thrust or force on an object for purposes of providing useful work using single low frequency signals. Efficient means of transforming electrical energy into sound may improve the operation of such a thrust application.

### SUMMARY

A method and system for generating a single frequency sound using a diaphragm coupled to a rotary motor. In an embodiment, the motor actuated single frequency speaker may be used in converting electrical and heat energy into useful mechanical energy. The motor driven acoustic oscillator, or speaker, may be used to generate a low frequency (LF) sound that imposes thrust on an object. Moreover, because of the characteristics of the LF sound, heat energy from the surrounding fluid medium of the speaker may be converted into additional thrust on the object. In one embodiment, the motor actuated single frequency speaker, or sonic piston, may be connected to an object, where both the piston and object are disposed in a fluid medium. In this embodiment, the sonic piston may be directed along an axis of travel. The sonic piston creates a vacuum at an end of the object facing the direction of travel while ambient pressure is at an opposing end to generate thrust on the object in the direction of the vacuum and along the axis of travel. In a further embodiment, a plurality of sonic pistons, or speakers, may be used for levitation of an object.

### DRAWINGS

The disclosed methods and apparatuses are described more or less diagrammatically in the accompanying drawings wherein:

FIG. 1 illustrates a general loudspeaker using a voice coil;

FIG. 2 illustrates an embodiment of a loudspeaker driven using an electrical motor;

FIG. 3A illustrates a disassembled view of the loud speaker of FIG. 2;

FIG. 3B illustrates a partially assembled view of the loud speaker;

FIG. 3C illustrates a fully assembled external view of the loudspeaker embodiment;

FIG. 4 illustrates an electric rotary motor;

FIG. 5A illustrates a spherical object to be moved by an embodiment of a motor driven single frequency speaker, or sonic piston; and

FIG. 5B illustrates a spherical object being moved by a sonic piston.

FIG. 6 illustrates an embodiment of a motor driven single frequency speaker having a flat diaphragm and boxed shaped housing;

FIGS. 7A and 7B illustrates an embodiment of a motor driven single frequency speaker having a frusto-pyramidal diaphragm with a frusto-pyramidal housing;

FIG. 8 illustrates an embodiment of a motor driven single frequency speaker having a frusto-pyramidal diaphragm and a boxed shaped housing;

FIG. 9A illustrates a square diaphragm;

FIG. 9B illustrates a circular diaphragm; and

FIG. 10 illustrates an embodiment of a motor driven single frequency speaker having a flat diaphragm and a frusto-pyramidal housing.

### DESCRIPTION

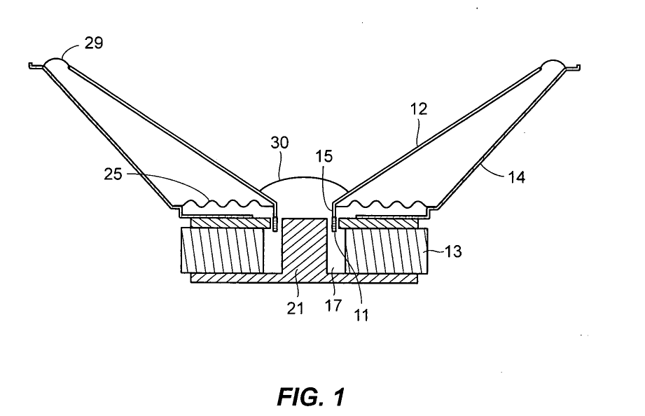

FIG. 1 illustrates a general acoustical loud speaker 10 having a voice coil 11. The traditional design includes a lightweight semi-rigid cone 12, a coil of fine wire 11, a circular magnet 13, and a rigid support structure 14. The coil 11 (known as the voice coil) is attached to the apex 15 of the cone 12. A gap 17 is a small circular hole, slot or groove which allows the voice coil and cone to move back and forth. The coil 11 is oriented coaxially inside the gap 17. The gap 17 is established between the permanent magnet 13 and a center post 21, or pole-piece. The gap 17 is where the magnetic field is most concentrated. One magnetic pole is outside the coil 11 and another is inside the voice coil 11. Additionally, a dynamic speaker 10 may also include a suspension system to keep the coil 11 centered and to make the speaker components return to a neutral point after moving. A typical suspension system includes a spider 25, or damper, which is coupled near the apex 15 of the cone 12 and the surround 29 (or “bellows”), which is usually made of rubber or foam and attached at the outer circumference of the cone. The various parts are precisely held together by a chassis, basket, or frame 14. A dust cap 30 may be used to prevent unwanted particles from interfering with the motion of the diaphragm 12 around the pole 21.

When an electrical signal is applied to the voice coil 11, a magnetic field is induced by the electric current in the coil 11 which becomes an electromagnet. The coil 11 and the permanent magnet 13 interact magnetically, generating a force which causes the coil 11 and the semi-rigid cone 12, or diaphragm, to move back and forth and thereby reproduce sound at the frequency of the applied electrical signal. When a complex signal is applied, the cone vibration that results is a reproduction of the applied signal as a sound wave from the speaker driver.

Voice coil based speakers may be adequate in general applications involving a variable frequency signal, such as speech or music, where the relatively free sliding movement of the cone along the pole enables various harmonics to be introduced and synthesized. However, in applications in which energy efficiency is a primary concern, voice coil mechanisms may not be efficient enough in electrical energy conversion into sound or mechanical energy. In particular, the amount of energy that is wasted in voice coil operation may not provide an efficient electrical to mechanical transformation when only single frequency signals are desired.

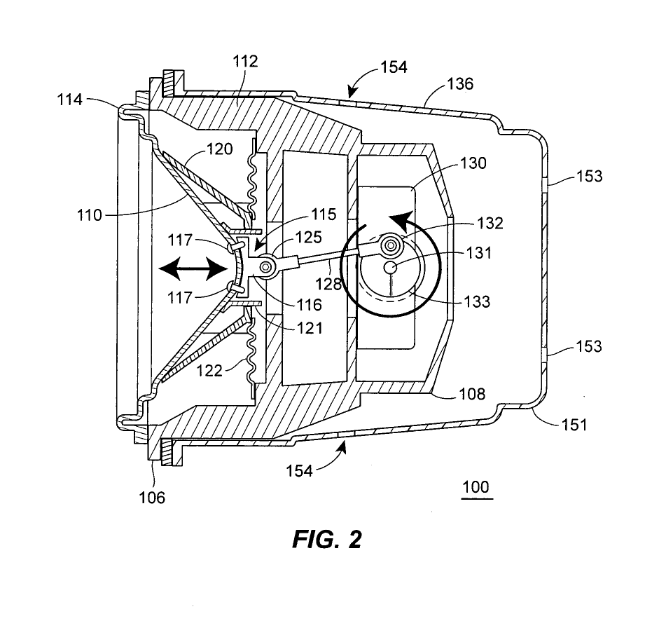

FIG. 2 illustrates a perspective view of an embodiment of an acoustic speaker 100 using a rotating electrical motor. A cone shaped diaphragm 110 is attached to a frame 112 using a surround 114 at a front end 106 of the speaker frame 112. The cone may be made of any suitable material that is sufficiently flexible to be driven by forces applied at an apex, and strong enough to withstand tearing. In one embodiment, the cone or diaphragm may comprise a carbon fiber material. The cone 110 is attached at its apex to a mount 115. In this embodiment, the mount may comprise a plate or bracket 116 coupled to the apex via one or more screws 117. To assist in stabilizing the cone 110, a support frame 120 may be used to hold a segment of the cone 110. The support frame 120 may be coupled to a mounting bracket 121, and/or a spider 122.

The apex mounting bracket 116 may be attached to any suitable mechanical joint 125 that movably couples the bracket 121 to a rod 128. In the embodiment of FIG. 2, the mechanical joint 125 is a pin joint. An electrical motor 130 is mounted on the speaker frame 112 near a rear end 108 of frame 112. In this embodiment, the motor 130 is mounted so that its rotating shaft 131 is perpendicular to a plane containing the base of the cone 110. The rotor shaft 131 is coupled to a disk 133 which is attached to the rod 128 using a second pin joint 132. The rotor shaft 131, disk 133, and rod 130 form a crank. As the rotor 131 turns around its axis, a torque is applied to the disk 133, thereby rotating the disk 133. The rod 128 that is coupled to the first joint 125 and second pin joint 132 imparts a back and forth motion to the cone 110. A housing 136 may be used to enhance fluid dynamics of the sound emanating from the diaphragm. For example, in applications requiring directional sound, the housing may be used to further direct the sound waves towards the front of the diaphragm 110.

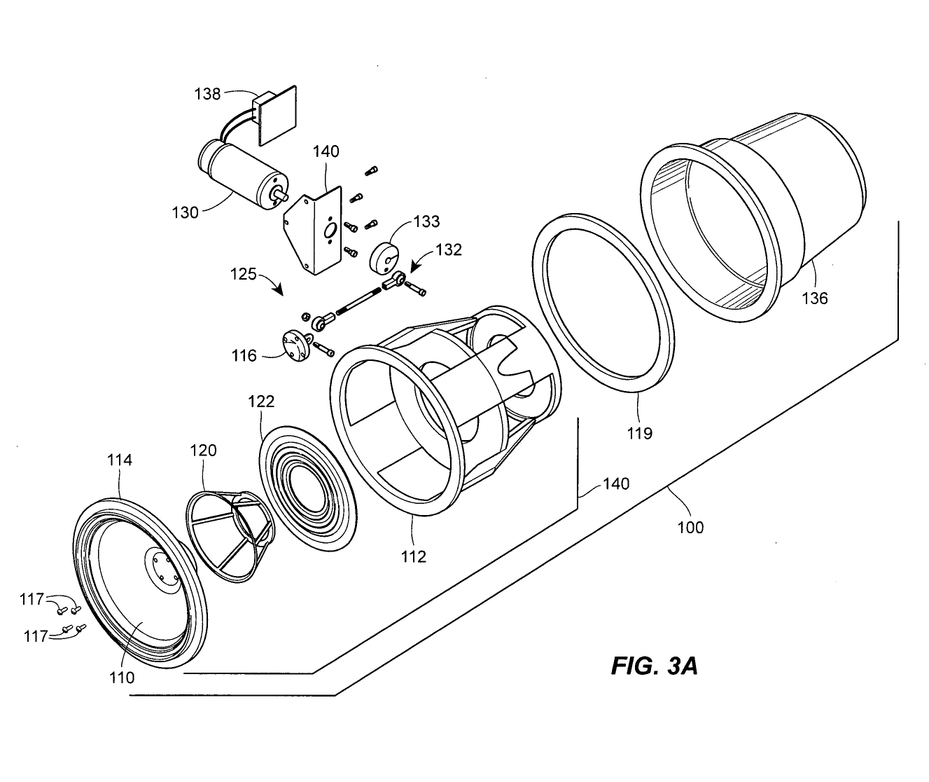

A disassembled perspective view of the acoustic oscillator is shown in FIG. 3A. Similar components of FIG. 2 shown in FIG. 3A are illustrated with similar numbering. An additional spacer 119 may be used to secure the housing 136 to the frame 112. The motor 130 further includes a power supply 138. A motor mounting bracket 140 is additionally shown to attach the motor 130 to the mounting frame 112. A portion of the speaker assembly 100 without the housing is illustrated as section 140 and assembled as illustrated in FIG. 3B. FIG. 3C illustrates an assembled view of the speaker of FIG. 2.

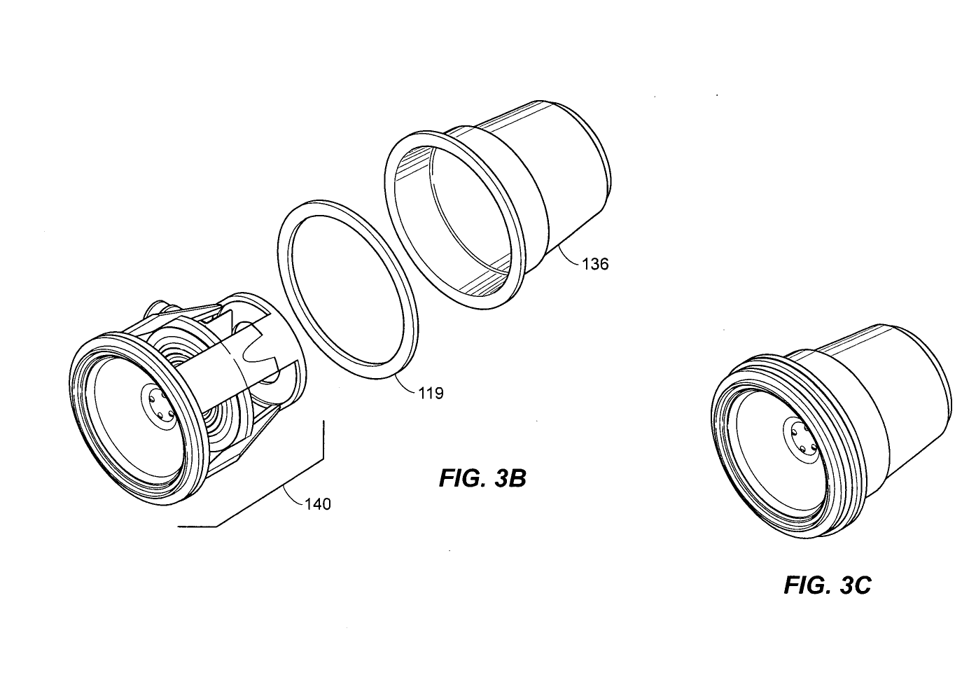

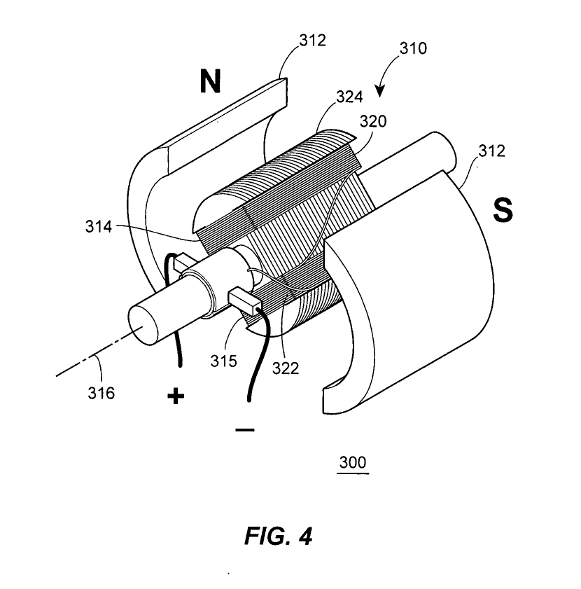

The motor 130 used to drive the diaphragm 110 and thereby produce the constant sound signal may be a rotary motor. An example of such a motor is illustrated in FIG. 4. In a rotary motor 300, the rotating part (usually on the inside) is called the rotor 310, and the stationary part is called the stator 312. The rotor 310 rotates because wires 314, 315 and a magnetic field from the stator 312 are arranged so that a torque is developed about the rotor's axis 316. The motor 300 generally contains electromagnets 320 and 322 that are wound on a frame 324. The frame 324 may be called an armature. The armature 324 is the part of the motor 300 across which the input voltage is supplied. Depending upon the design of the machine, either the rotor 310 or the stator 312 can serve as an armature. In a acoustic thrust application, the motor 300 may be a constant speed DC motor that is commonly used in the art. Such as constant speed DC motor may provide a constant angular velocity for its rotor. A constant speed DC motor may further stabilize oscillation frequency. DC motors may be more efficient in certain single frequency sound applications because of the constant current and voltage.

Motor design parameters, such as speed of rotation, may be selected to provide the required rotational speed to produce a desired single frequency of oscillation. Because voice coil based speakers are designed to respond to changing electrical signals (representing, for example, music and voice sounds), many harmonics may be generated. Further, the sliding diaphragm and spider configuration may not provide enough control over the motion of the diaphragm when producing sound using the voice coil, thereby expending wasted energy. The illustrated embodiment, on the other hand, uses an electric motor to provide a more efficient process for translating electrical energy into single frequency sound energy. In the illustrated embodiments, the motor provides a single known rotational speed that drives the diaphragm to generate a specific single harmonic sound wave. Because the movement of the diaphragm is strictly controlled by, the mechanical joints and control rod, there is less wasted motion due to, for example, momentum shifting of a voice coil.

The acoustic speaker or oscillator of FIG. 2 may be used in a further embodiment to produce thrust by generating a constant low frequency sound wave in accordance with the formulas described below. A low frequency speaker representing a sonic piston may be externally attached to an object immersed in a fluid medium (e.g., air) to move the object. The low frequency sound waves generated by the acoustic speakers can move the fluid in which an object is immersed away from the region of the speakers thereby producing a vacuum or very low pressure region in front of the acoustic speaker. The side of an attached object opposite to the speaker will have normal fluid pressure, resulting in a force acting on the object in the direction of the low frequency acoustic speaker.

While not being bound to any particular theory, the following is an example of how to use single low frequency sound waves (generated, for example, by the speaker embodiment described above) to obtain thrust on and levitation of an object. The sound energy is used in order to transform potential energy in a fluid into useful mechanical energy or work.

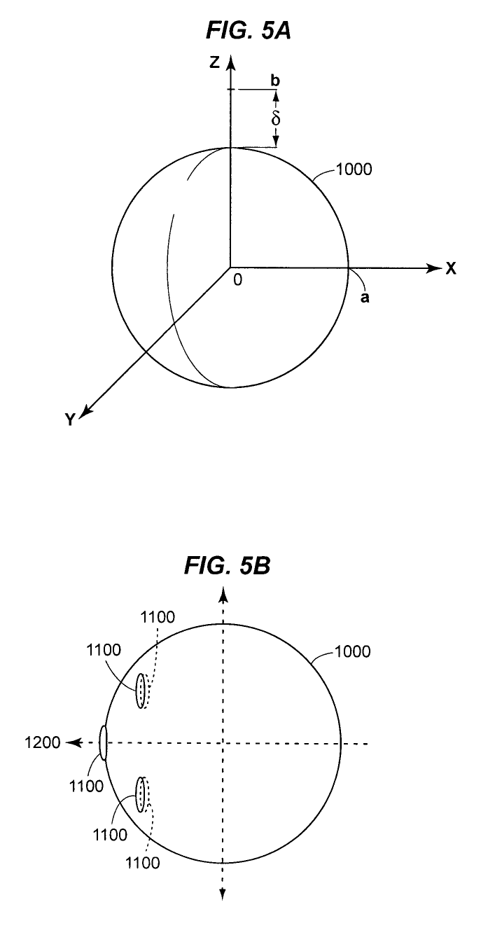

An object to be propelled or levitated may be a sphere of radius 50 cm, and the low frequency acoustic oscillator, or speaker, as shown in FIG. 5A may produce 1000 watts of sound energy. The oscillator may be placed at a distance of 0.014 cm from the surface of the sphere and is located outside of the sphere. The thrust on the sphere will be shown to be 3725 poundals, which can be used to lift a mass of 116 pounds. The ratio R of the useful mechanical energy output which does the work of propulsion or levitation over the input in the form of acoustic wattage is R=23.4×(10)⁸w^{1/3}τ where w is the wattage of the oscillator and τ is the time in seconds during which the oscillator has been activated.

Euler's Equations are used to describe the fluid (i.e., the atmosphere) surrounding the object. This assumption is reasonable provided that the frequency f is less than or equal to 4000 Hz (to be discussed further below in the Low Frequency Section).

On the other hand, the closer that the oscillator is disposed to the sphere, the greater the thrust. In this analysis, as shown in FIG. 1A, “a” is the radius of the sphere, “b” is the distance of the oscillator from the center of the sphere, and δ is the distance that the oscillator is disposed from the outer surface of the sphere, so that b=a+δ.

In an example, δ=0.014 cm, and Euler's equations of ideal fluid flow may be used to derive the conclusions. This is consistent with the assumption that b=a+δ. Also, ρ is the constant density of the fluid and P is the fluid pressure. For f≦ about 350 Hz, the velocity q of the fluid is given as the negative gradient of a potential φ. Under the above assumptions, a time dependent version of Bernoulli's equation results in:

$$- {\partial }_{t} φ + \int \frac{1}{ρ} d P + \frac{q \cdot q}{2} = C ( t ) ,$$

where C(t) depends only on the time t.

The oscillating sound may be described by a velocity potential of the form

$$φ = \frac{A cos ω t}{R}$$

where R=\sqrt{r²−2 r b cos θ+b²}, where r=\sqrt{x²+y²+z²} and cos θ=z/n; ω is the frequency of the oscillator; t is time measured in seconds; x, y, z, r and b are measured in centimeters; and “A” has the dimensions of

$$\frac{{cm}^{3}}{sec} .$$

φ can be expanded in a series of Legendre polynomials Pₙ, as:

$$φ = \frac{A cos ω t}{b} {\sum }_{n = 0}^{∞} {P}_{n} ( cos θ ) {( \frac{r}{b} )}^{n} .$$

In the absence of a sphere the fluid flow velocity v is given by v=−∇φ. The normal derivative on the surface of the sphere r=a is given by

$${\partial }_{r} φ ( r = a ) = \frac{A cos ω t}{b} {\sum }_{n = 0}^{∞} \frac{{nP}_{n} ( cos θ ) {a}^{n - 1}}{{b}^{n}} .$$

An additional potential Ψ is in the form

$$ψ = {\sum }_{n = 0}^{∞} {{c}_{n} ( {\partial }_{z} )}^{n} ( \frac{1}{r} ) , {\partial }_{z} r = \frac{r}{z} ,$$

where the constants cₙ are determined so that the total potential

$$Φ = \frac{A cos ω t}{b} {\sum }_{n = 0}^{∞} {P}_{n} ( cos θ ) {( \frac{r}{b} )}^{n} + {\sum }_{n = 0}^{∞} {{c}_{n} ( {\partial }_{z} )}^{n} ( \frac{1}{r} )$$

satisfies the condition that the velocity q=−∇φ is tangential to the surface of the sphere r=a.

Using a well known formula for Legendre polynomials

$${P}_{n} ( μ ) = \frac{{( - 1 )}^{n} {r}^{n + 1}}{n !} {( {\partial }_{z} )}^{n} ( \frac{1}{r} )$$

where μ=cos θ=z/r. Thus, Φ may be rewritten as

$$Φ = A cos ω t {\sum }_{n = 0}^{∞} {P}_{n} ( μ ) \frac{{r}^{n}}{{b}^{n + 1}} + {\sum }_{n = 0}^{∞} \frac{{( - 1 )}^{n} n ! {c}_{n} {P}_{n} ( μ )}{{r}^{n + 1}} \cdot - {\partial }_{r} Φ ( r = a )$$

is the component of the fluid velocity normal to the surface of the sphere (r=a).

This must satisfy the boundary condition o=−∂ᵣΦ(r=a). Thus,

$${\partial }_{r} Φ = A cos ω t {\sum }_{n = 0}^{∞} \frac{{nP}_{n} ( μ ) {r}^{n - 1}}{{b}^{n + 1}} + {\sum }_{n = 0}^{∞} \frac{{( - 1 )}^{n + 1} ( n + 1 ) ! {c}_{n} {P}_{n} ( μ )}{{r}^{n + 2}} .$$

Setting ∂ᵣΦ=o for (r=a), then

$${c}_{n} = \frac{{( - 1 )}^{n} {na}^{2 n + 1} A cos ω t}{( n + 1 ) ! {b}^{n + 1}} .$$

This gives

$$Φ = A cos ω t {\sum }_{n = 0}^{∞} \frac{{P}_{n} ( cos θ )}{{b}^{n + 1}} ( {r}^{n} + \frac{{na}^{2 n + 1}}{( n + 1 ) {r}^{n + 1}} ) .$$

The tangential velocity on the surface of the sphere (r=a) is

$$\begin{matrix}{q}_{tan} = - \frac{1}{r} {\partial }_{θ} Φ ( r = a ) \\ = A cos ω t {\sum }_{n = 0}^{∞} \frac{{a}^{n - 1}}{{b}^{n + 1}} ( \frac{2 n + 1}{n + 1} ) sin θ {P}_{n}^{′} ( cos θ ) .\end{matrix}$$

Next Bernoulli's Law may be used to compute the pressure P. In particular,

$$P = \frac{- ρ ∇ Φ \cdot ∇ Φ}{2} + ρ C ( t ) + ρ {\partial }_{t} Φ . \\ ∇ Φ . ∇ Φ ( r = a ) = {{A}^{2} ( cos ω t )}^{2} {( sin θ )}^{2} {( {\sum }_{n = 0}^{∞} \frac{{P}_{n}^{′} ( cos θ ) {a}^{n - 1}}{{b}^{n + 1}} ( \frac{2 n + 1}{n + 1} ) )}^{2} , and$$

$${\partial }_{t} Φ ( r = a ) = - ω A sin ω t {\sum }_{n = 0}^{∞} \frac{{P}_{n} ( cos θ ) {a}^{n}}{{b}^{n + 1}} ( \frac{2 n + 1}{n + 1} ) .$$

The element of surface area

$$d \sum = {a}^{2} sin θ d θ d φ$$

where 0≦θ≦π, 0≦φ≦2π. The thrust T which is in the z-direction is given by

$$\begin{matrix}T = - {\int }_{0}^{π} {\int }_{0}^{2 π} P {a}^{2} cos θ sin θ d φ d θ \\ = - 2 π {a}^{2} {\int }_{0}^{π} P cos θ sin θ d θ .\end{matrix}$$

$$Using μ = cos θ , then T = 2 π {a}^{2} {\int }_{- 1}^{1} P μ d μ , and$$

$${\int }_{- 1}^{1} ρ C ( t ) μ d μ = ρ C ( t ) ( \frac{{( - 1 )}^{2}}{2} - \frac{{1}^{2}}{2} ) = 0.$$

$$T = - π ρ {A}^{2} {{a}^{2} ( cos ω t )}^{2} {\int }_{- 1}^{1} ( 1 - {μ}^{2} ) {( {\sum }_{n = 0}^{∞} ( \frac{{P}_{n}^{′} ( μ ) {a}^{n - 1}}{{b}^{n + 1}} ( \frac{2 n + 1}{n + 1} ) ) )}^{2} μ d μ - 2 π ρ {a}^{2} A ω sin ω t {\int }_{- 1}^{1} μ {\sum }_{n = 0}^{∞} \frac{{P}_{n} ( μ ) {a}^{n - 1}}{{b}^{n + 1}} ( \frac{2 n + 1}{n + 1} ) d μ .$$

This can be evaluated using b>a to give

$$T = \frac{4 π ρ {A}^{2} {a}^{3} {cos}^{2} ω t}{{b ( b + a )}^{2} {( b - a )}^{2}} + \frac{2 π ρ ω {a}^{3} A sin ω t}{{b}^{2}} .$$

Next, the power output is computed. The source has the form

$$Φ = \frac{A cos ω t}{r}$$

where for the immediate purpose of computation only, the source is at the origin.

$$V Φ \cdot V Φ = \frac{{A}^{2} {cos}^{2} ω t}{{r}^{4}} .$$

“<quantity>” may be used herein to denote the average value of a quantity over a period of time.

$$< ∇ Φ \cdot ∇ Φ >= \frac{{\int }_{0}^{2 π {ω}^{- 1}} ∇ Φ \cdot ∇ Φ d t}{2 π {ω}^{- 1}} = \frac{{A}^{2}}{2 {r}^{4}} .$$

The surface area of a sphere of radius r surrounding the source is 4πr², which may be taken to equal 1 cm². This gives

$$r = {( \frac{1}{4 π} )}^{1 / 2} cm .$$

The element of surface area is

$$d \sum = {r}^{2} sin θ d φ d θ = \frac{sin θ d φ d θ}{4 π} {cm}^{2} \cdot {( < ∇ Φ \cdot ∇ Φ > )}^{3 / 2} = \frac{{A}^{3}}{{2}^{3 / 2} {r}^{6}} .$$

The power output (W watts) is

$$\frac{ρ}{2} \int \int < ∇ Φ \cdot ∇ Φ {>}^{3 / 2} d \sum = \frac{{( 4 π )}^{3} ρ {A}^{3}}{{2}^{5 / 2} {cm}^{4}} .$$

### Thus,

$$W watts = \frac{{( 4 π )}^{3} ρ {A}^{3}}{{2}^{5 / 2} {cm}^{4}} ,$$

and using

$$1 watt = \frac{{( 10 )}^{7} gram {cm}^{2}}{{sec}^{3}} ,$$

and taking for air

$$ρ = \frac{1.293 \times {( 10 )}^{- 3} gram}{{cm}^{3}} ,$$

results in

$$A = 285.5 {w}^{1 / 3} \frac{{cm}^{3}}{sec} .$$

The acoustic boundary layer is given by

$$δ \sqrt{\frac{va}{c}} .$$

a is 50 cm in this example, c is the speed of sound at

$$340.3 \frac{meters}{sec} , \\ v = kinematic viscosity of air = \frac{μ}{ρ} , \\ and μ = viscosity of air = 180 \times {( 10 )}^{- 6} \frac{dyne sec}{{cm}^{2}} .$$

### Thus,

$$v = .1453 \frac{{cm}^{2}}{sec} .$$

This gives δ=0.0146 cm. Returning to the formula for the thrust:

$$T = \frac{4 π {ρ}^{2} {A}^{2} {a}^{3} {cos}^{2} ω t}{{b ( b + a )}^{2} {( b - a )}^{2}} + \frac{2 π ρ {Aa}^{3} ω sin ω t}{{b}^{2}} .$$

The first term, which is nonnegative, may be made to dominate the second term, which varies in sign. To this end, the parameters are chosen so that

$$\frac{4 π ρ {A}^{2} {a}^{3}}{2 {b ( b + a )}^{2} {( b - a )}^{2}} ≫ \frac{2 π ω ρ {Aa}^{3}}{{b}^{2}} .$$

Setting b=a+δ, a=50 cm, δ=0.0146 cm, and since δ is small compared to a and b, then

$$23.46 \frac{A}{{cm}^{3}} ≫ ω .$$

Next, take

$$A = 285.5 {w}^{1 / 3} \frac{{cm}^{3}}{sec}$$

and define the dimensionless frequency by f=Ω sec to obtain 6697 W^{1/3}>>f. Replacing cos² ωt by it's average value over a period

$$< {cos}^{2} ω t >= \frac{1}{2} , then T = ( 515 \text{,} 314 {W}^{2 / 3} dynes ) .$$

Also using 1 dyne=7.23×10⁻⁵ poundals, results in T=37.25 W^{2/3} poundals, where 1 poundal is the force necessary to accelerate a 1 pound mass 1 foot per second per second.

In this above example, heat energy in a fluid (the atmosphere for example) is converted into useful mechanical work. Using the ideal gas law P=PRT, the heat energy is equivalent to treating the pressure as a potential energy. Using m=mass in pounds of object moved; z=distance that the object moves measured in feet; t=time measured in seconds; T=thrust measured in poundals, then:

$$m \ddot{z} = T ; z ( 0 ) = 0 ; \dot{z} ( 0 ) = 0 , m \dot{z} = tT ; and mz = \frac{{t}^{2}}{2} T .$$

### Additionally,

$$E = \frac{{T}^{2} {t}^{2}}{2 m} = work produced in t = τ sec .$$

in t=r sec. I=the energy entering the fluid from the acoustic oscillator. I=wπwatt sec.

The ratio of output energy to input energy is denoted by R.

$$R = \frac{E}{I} = \frac{{T}^{2} {t}^{2}}{2 m} / w τ watt sec ,$$

thus,

$$R = \frac{29.2 {w}^{1 / 3} τ lbm}{m} ,$$

and setting m=100 lbm, w=1000, π=60, then for the example, R=175.
For a mass of m lbm, a weight of 32 m lbf results, where

$$g = 32 \frac{ft}{{sec}^{2}} .$$

The thrust is T=37.25 W^{2/3} lbf . For example, taking W=1000 results in T=3725 lbf. This force will lift a mass of m pounds provided: 32 m<3725 or m<116 pounds.

### Low Frequency Conditions

The term “low frequency” (f) as used above to describe the sound signal produced by the low frequency oscillators, may represent three low frequency conditions that, if satisfied, may support the above derivations and equations. First, if the frequency of the oscillator, f, is less than about 10,000 Hz, the viscosity term in the Navier-Stokes equation may be neglected in modeling the effect of a sound source when the source is within a few centimeters (e.g., 10 cm) from the body to be influenced. Second, when f is less than about 350 Hz, the velocity potential for the fluid may be assumed to satisfy Lapalace's equation. Third, in one mathematical model, the oscillator may be treated as a point source which produces a divergent solution when an oscillator is placed on the surface of the body to be influenced. This contrasts with placing a physical oscillator on the surface of the physical body. This difficulty in the mathematical model is avoided by setting the oscillator at a small positive distance from the body. This distance is given a term that is labeled an “acoustic boundary layer” by analogy to the standard boundary layer of fluid mechanics where the fluid velocity v is replaced by the sound velocity c.

As discussed above, the first low frequency condition may enable the viscosity term in the Navier-Stokes equations of fluid motion used above to be neglected. This first low frequency condition may be illustrated using the following basic fluid equations (See “The Theory of Sound by Lord Rayleigh,” volume 2, page 316, Dover 1945):

u=Ae^{-αx} cos(nt−βx)
u is the amplitude of a sound wave.

$$β = \frac{n}{c} , α = \frac{8 {π}^{2} μ}{3 {λ}^{2} ρ c}$$

c=sound speed.
As is known:

$$λ = \frac{c}{f}$$

λ is the wavelength;
f is the frequency measured in hertz;
ρ is the density of the fluid; and
x is the distance measured from a solid boundary at x=0 measured in centimeters.

Thus,

$$n = \frac{2 π f}{c} ,$$

and α can be rewritten as

$$α = \frac{8 {π}^{2} {f}^{2} μ}{3 ρ {c}^{3}} .$$

Provided αx<<1 the exponential damping and hence the effect of the viscosity μ can be neglected. f may thus be chosen so that:

$$\frac{8 {π}^{2} {f}^{2} μ x}{3 ρ {c}^{3}} << 1 or f << \sqrt{\frac{3 ρ {c}^{3}}{8 {π}^{2} μ x}} .$$

This is one condition in which the frequency, f, is low, and if satisfied, effectively enables the viscosity term in the Navier-Stokes equation to be ignored.

A second low frequency condition may enable the approximation of fluid velocity to be q=−∇φ, where φ satisfies Laplace's equation:

$$\frac{{\partial }^{2} φ}{\partial {x}^{2}} + \frac{{\partial }^{2} φ}{\partial {y}^{2}} + \frac{{\partial }^{2} φ}{\partial {z}^{2}} = 0 ,$$

where x, y and z are an orthonormal set of coordinates. The fluid may be assumed to be irrotational so that q=−∇φ.

For an acoustic wave, the non-linear terms in the Navier-Stokes equation may be ignored and if the first low frequency condition above is satisfied, the viscosity term may be neglected to result in:

$$\frac{1}{{c}^{2}} \frac{{\partial }^{2} φ}{\partial {t}^{2}} - \frac{{\partial }^{2} φ}{\partial {x}^{2}} - \frac{{\partial }^{2} φ}{\partial {y}^{2}} - \frac{{\partial }^{2} φ}{\partial {z}^{2}} = 0 ,$$

where c is the velocity of sound and t is time. Assuming that

$$φ = A cos ( 2 π f t - \frac{2 π x}{λ} ) , λ f = c , \\ then$$

$$\frac{1}{{c}^{2}} \frac{{\partial }^{2} φ}{\partial {t}^{2}} = \frac{4 {π}^{2} {f}^{2} A}{{c}^{2}}$$

$$and$$

$$\frac{{\partial }^{2} φ}{\partial {x}^{2}} + \frac{{\partial }^{2} φ}{\partial {y}^{2}} + \frac{{\partial }^{2} φ}{\partial {z}^{2}} = \frac{4 {π}^{2} A}{{λ}^{2}}$$

$$and$$

$$\frac{1}{{c}^{2}} \frac{{\partial }^{2} φ}{\partial {t}^{2}}$$

is small compared to

$$\frac{{\partial }^{2} φ}{\partial {x}^{2}} + \frac{{\partial }^{2} φ}{\partial {y}^{2}} + \frac{{\partial }^{2} φ}{\partial {z}^{2}} ,$$

provided that

$$\frac{{f}^{2}}{{c}^{2}} << \frac{1}{{λ}^{2}} or f << \frac{c}{λ} .$$

λ may be chosen to be an order of magnitude in a range of the size of the object to be propelled or levitated. In the above sphere example, λ=a. This may represent a second low frequency condition. A small f in this case may justify the assumption that φ satisfies Laplace's equation:

$$\frac{{\partial }^{2} φ}{\partial {x}^{2}} + \frac{{\partial }^{2} φ}{\partial {y}^{2}} + \frac{{\partial }^{2} φ}{\partial {z}^{2}} = 0$$

A third low frequency condition is now described. The following formula was derived above for the thrust T acting on a sphere of radius a:

$$T = \frac{4 πρ {A}^{2} {a}^{3} {cos}^{2} ω t}{{b ( b + a )}^{2} {( b - a )}^{2}} + \frac{2 πρ {wAa}^{3} sin ω t}{{b}^{2}} ,$$

where b=a+δ and δ≧0. b is the distance in centimeters of an oscillating diaphragm from the center of a sphere of radius a cm. Due to the presence of the term sin ωt, the second term of T varies in sign.

The first term of T is always ≧0. cos² ωt may be replaced by an average value over a period <cos² ωt>=½ and the following condition may result in:

$$\frac{2 πρ {A}^{2} {a}^{3}}{{b ( b + a )}^{2} {( b - a )}^{2}} >> \frac{2 πρω {Aa}^{3}}{{b}^{2}} ,$$

which guarantees a constant direction for the thrust. Setting δ=b−a and taking δ>0 to be small compared to both a and b, the above equation is equivalent to

$$\frac{A}{4 a {δ}^{2}} >> ω = 2 π f .$$

This may represent the third low frequency condition.

The following illustrates an example of calculating the three low frequency conditions using the above formulas:

$$v = \frac{μ}{ρ} = .1453 \frac{{cm}^{2}}{sec} , \\ α = \frac{8 {π}^{2} {f}^{2} μ}{3 ρ {c}^{3}} , \\ and$$

$$c = 340.3 \frac{meters}{sec}$$

$$gives$$

$$α = 6.786 \times {10}^{- 13} \frac{{sec}^{2}}{cm} {f}^{2} .$$

Setting x=100 cm, then αx=66.786×10⁻¹² sec² f²<<1, which gives f<<122,365 hertz. Thus, the first condition in this example may be satisfied when f≦10,000 hertz.

For λ=2a=100 cm (the diameter of the sphere in the above example), f<<340 hertz, which represents the second condition.

Next, using

$$\frac{A}{4 a {δ}^{2}} >> ω = 2 π f , a = 50 cm , A = 285.5 {w}^{\frac{1}{3}} \frac{{cm}^{3}}{sec} and$$

δ=0.0146 cm results in: 6696.8 w^{1/3}>>ω=2πf. A third condition may be when f<<10,658 hertz.

To obtain the vacuum based thrust as described above, the motor speed of a speaker, such as that illustrated in FIG. 2, may be selected to provide a diaphragm frequency according to the above low frequency conditions. In one embodiment, the rotational velocity of the motor may be adjustable to allow for tuning the frequency of oscillation. In this embodiment, the speed of the motor may be adjusted using any number of techniques known in the art. For example, an electric circuit (comprising, for example, a variable resistor) may be used to adjust the applied voltage to the windings. Alternatively, a mechanical method of adjusting rotor speed may be used, such as adjusting the physical spacing of the windings.

It should also be noted that the parameters of the general speaker design of FIG. 2 may be modified to accommodate for a desired thrust and further based on the shape, size, and mass of an object in which the thrust is to be applied. Also, while a spherical object is described in the above embodiment, objects having other shapes and sizes may also be used.

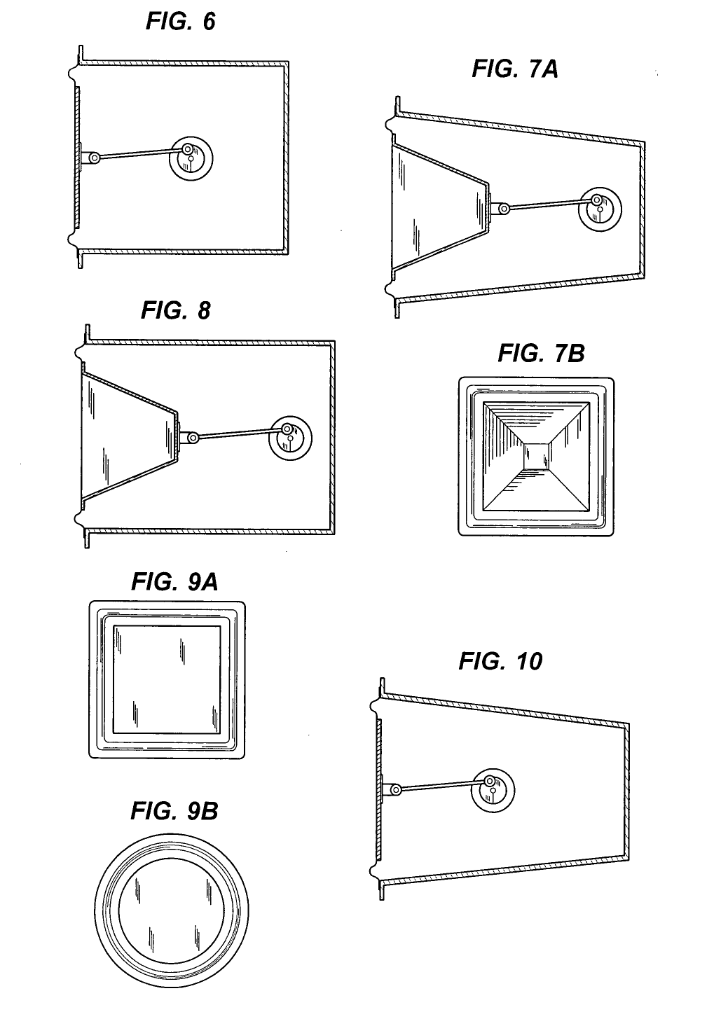

In an embodiment of the motor actuated speaker illustrated in FIG. 6, the shape of the diaphragm may be flat, rather than conical. While a conical shaped diaphragm may be suitable for directing voice and musical sounds, a flat diaphragm may be more efficient in creating the vacuum effect described above. Other diaphragm shapes other than conical or flat shapes may be used depending on the application of the motor actuated speaker.

Also, the shape of the housing 136 may be designed to create an appropriate surrounding fluid distribution around and within the acoustic oscillator 100. For example, In the embodiment of FIG. 2, the housing may be selected to a be a cone shaped housing that hugs the frame 112 closely around the front end 106 of the speaker 100 and that tapers to a back 151, thereby forming a frusto-conical shaped housing. The housing back 151 may contain one or more openings 153 to allow for fluid flow. For example, the size and shape of the hole(s) 153 may be dependent on the frequency of oscillation. They may also depend on other general dimensions of the housing and cone as well as the shape of the inner fluid passageways surrounding the mounting frame 112. Additional holes 154 may be disposed on the side of the housing 136 between the diaphragm 110 and back 151.

Furthermore, the dimensions of the housing may be dependent on the resonant frequency and the shape of the diaphragm 110. In particular, the length of the frusto-conical housing 136 may be modified to produce different flow patterns in front of the speaker, which may increase or decrease thrust. In the embodiments described above, the diaphragm 110 and corresponding frame 112 and housing 153 are illustrated as circular conical. In other housing embodiments, the diaphragm may be frusto-pyramidal (as illustrated in FIGS. 7A and 7B) with a frusto-pyramidal frame and housing (FIG. 7A) or a boxed shaped frame and housing (as illustrated in FIG. 8). For flat diaphragms, the diaphragm may be square (FIG. 9A), circular (FIG. 9B), or any other appropriate shape. Also, any combination of the described elements may be within the scope of this invention. For example, a flat diaphragm having either a box shaped housing (as illustrated in FIG. 6) or a frusto-pyramidal housing (FIG. 10) may be implemented depending on the thrust application.

The speaker embodiment of FIG. 2 illustrates a separate frame 112 and housing 136. In an alternative embodiment, the housing and speaker may be integrally formed with each other. In other words the housing and speaker may be created as a single component. In another embodiment, a single channel may be formed between the diaphragm 110 and the back of the housing 151. This may promote a more efficient circulation of fluid within the housing 136 and increase thrust.

The speaker embodiment of FIG. 2 illustrates that the drive rod 128 and motor are positioned along a direct line between the center of the diaphragm 110 and the center of the back of the housing 151. In this configuration, the motor and/or drive rod may present an obstruction to the fluid flow within a center channel defined between the diaphragm 110 and the back of the housing 151. In a further embodiment, the motor 130 may be positioned at an offset from the center channel. The drive rod may also be offset accordingly. In a further embodiment, the mounting 115 may be attached to the diaphragm in an offset position from the apex of the diaphragm 110. In yet a further embodiment, a plurality of motors may be used to move the diaphragm.

FIG. 5B illustrates a spherical object 1000, that is attached to several acoustic speakers or oscillators 1100. In operation, the acoustic oscillators 1100 may be configured to produce thrust on the object 1000 to move the object 1000 in a direction indicated by arrow 1200. Although not shown in FIG. 5B, the speakers 1100 may include a mounting for attaching to the object 1000.

The embodiments described may provide a more efficient conversion of electrical energy to sound energy. In particular, existing voice coil based speakers may only perform electrical to sound conversion at an efficiency of 0.5%, while the claimed motor driven speaker may be able to more efficiently convert electrical energy into sound energy (e.g., in the form of a single frequency sound wave) at an efficiency of 90%.

Although the forgoing text sets forth a detailed description of numerous different embodiments, it should be understood that the scope of the patent is defined by the words of the claims set forth at the end of this patent. The detailed description is to be construed as exemplary only and does not describe every possible embodiment because describing every possible embodiment would be impractical, if not impossible. Numerous alternative embodiments may be implemented, using either current technology or technology developed after the filing date of this patent, which would still fall within the scope of the claims.

Thus, many modifications and variations may be made in the techniques and structures described and illustrated herein without departing from the spirit and scope of the present claims. Accordingly, it should be understood that the methods and apparatus described herein are illustrative only and are not limiting upon the scope of the claims.

What is claimed:

1. An acoustic oscillator for generating thrust comprising:
a housing member having a first and second opening;
a diaphragm enclosing the first opening of the housing member;
an electric motor having a rotor, the motor disposed within the housing member;
a first link assembly coupled to the rotor;
a second link assembly coupled to the diaphragm;
a drive rod coupled to the first link assembly and the second link assembly, wherein the first link assembly, second link assembly, and drive rod translate rotational movement of the rotor into movement of the diaphragm.

2. The acoustic oscillator of claim 1, wherein the motor is a constant velocity DC motor.

3. The acoustic oscillator of claim 1, wherein the diaphragm is flat.

4. The acoustic oscillator of claim 1, wherein the diaphragm is cone-shaped and wherein the apex of the cone-shaped diaphragm is disposed within the housing.

5. The acoustic oscillator of claim 4, further comprising a mounting frame that is disposed within the housing and attached to the first opening, wherein the mounting frame comprises:
a first plate for supporting the apex of the cone;
a second plate for mounting the motor.

6. The acoustic oscillator of claim 5, wherein the motor is mounted on the second plate such that the rotor is disposed perpendicular to the base of the diaphragm.

7. The acoustic oscillator of claim 6, wherein the rotor is coupled to a crank that drives the movable rod.

8. The acoustic oscillator of claim 5, wherein the mounting frame is integrally formed with the housing member.

9. The acoustic oscillator of claim 1, wherein the second opening is disposed on an opposite side of the housing member from the first opening.

10. The acoustic oscillator of claim 1, further comprising a third opening disposed on a side of the housing member between the first and second opening.

11. The acoustic oscillator of claim 1, wherein the first link assembly and the second link assembly are pin joints.

12. The acoustic oscillator of claim 1, wherein the diaphragm comprises a carbon fiber material.

13. A method for radiating single frequency sound waves from an electronic device, the method comprising:
enclosing a first port of a housing with a diaphragm;
moving the diaphragm using a rotor of an electric motor;
emitting sound waves from the diaphragm into the air;
emitting sound waves from the diaphragm into a cavity formed from the housing, wherein the cavity is acoustically coupled to a second port of the housing, the second port disposed on an opposite side of the housing from the diaphragm; and
emanating sound waves from the cavity through the second port into the air.

14. The method of claim 13, further comprising providing a third port disposed on a side of the housing between the first and second port.

15. The method of claim 13, wherein the motor is a constant velocity DC motor.

16. The method of claim 13, wherein the diaphragm is circular conical and the housing is frusto-conical.

17. The method of claim 13, wherein the diaphragm is square shaped and flat, and the housing is box shaped.

18. An acoustic oscillator for producing a single frequency sound wave comprising:
a frame comprising a set of mounting platforms;
a diaphragm having a perimeter attached along a first platform of the frame;
a first joint coupled to the diaphragm;
an electric motor having a rotor, the electric motor mounted to a second platform of the housing such that the rotor is perpendicular to the base of the diaphragm; and
a drive rod coupled to the first joint and the motor, wherein the motor drives the drive rod and the drive rod moves the diaphragm via the first joint.

19. The acoustic oscillator of claim 15, further comprising a housing member attached to the frame, wherein the housing member is conically shaped and tapers near a rear end of the housing away from the diaphragm, and further wherein the rear end of the housing includes at least one opening.

20. The acoustic oscillator of claim 19, wherein the diaphragm is flat and the housing member is box shaped.

21. The acoustic oscillator of claim 15, further comprising a mounting that couples to an object to be pulled.
